(19) United States
(12) Patent Application Publication
(10) Pub. No.: US 2025/0344003 A1
(43) Pub. Date: Nov. 6, 2025

(54) ANALOG-TO-DIGITAL CONVERTER AND CONTROL METHOD THEREOF, SIGNAL PROCESSING APPARATUS, IMAGE SENSOR, ELECTRONIC APPARATUS, AND STORAGE MEDIUM

(71) Applicant: CANON KABUSHIKI KAISHA, Tokyo (JP)

(72) Inventor: HITOSHI NASU, Tokyo (JP)

(21) Appl. No.: 19/188,168

(22) Filed: Apr. 24, 2025

(30) Foreign Application Priority Data
May 2, 2024 (JP) 2024-074921

(51) Int. Cl. H04N 25/78; H04N 23/76; H04N 25/51; H04N 25/63

(52) U.S. Cl. CPC H04N 25/78; H04N 23/76; H04N 25/51; H04N 25/63

(57) ABSTRACT

An analog-to-digital converter comprises: an analog-to-digital conversion unit that performs analog-to-digital conversion using ΔΣ modulation on an image signal output from pixels; a judgement unit that judges a gain to be applied to the image signal; and a control unit that controls a feedback amount used in the analog-to-digital conversion of the image signal by the analog-to-digital conversion unit based on the gain. The control unit controls the feedback amount smaller in a case where the gain is a first gain than in a case where the gain is a second gain smaller than the first gain.

### BACKGROUND OF THE INVENTION

### Field of the Invention

The present invention relates to an analog-to-digital converter and control method thereof, and a signal processing apparatus, an image sensor and an electronic apparatus using the same, and a storage medium, and more particularly to an analog-to-digital conversion technique using ΔΣ modulation.

### Description of the Related Art

In recent years, in CMOS image sensors, the number of pixels and speed to read out a signal from the pixels have been increasing. In order to cope with the increasing number of pixels and the increasing speed of reading a signal, a large number of analog-to-digital converters (ADCs) are arranged and operated in parallel. However, in the conventional slope-type ADCs, the parallel arrangement of a large number of ADCs increases the circuit size and power consumption, which becomes a new problem.

For this reason, a CMOS image sensor using a AΣ ADC has been proposed, which has a smaller circuit size, requires a lower voltage, and is capable of high-speed AD conversion compared to a slope-type ADC. Japanese Patent No. 3904111 discloses a configuration of a CMOS image sensor that uses AΣ modulation in an AD conversion circuit.

However, a slope-type ADC can apply gain during AD conversion by using different slope of the reference voltage during the conversion, whereas a AΣ ADC configured as in Japanese Patent No. 3904111 cannot apply gain during AD conversion. Therefore, in a AΣ ADC, a digital gain is applied in a signal processing unit after AD conversion, but the larger the digital gain, the lower the bit precision of the final output becomes.

Furthermore, since the digital gain amplifies noise together with the signal, the larger the digital gain, the more noticeable the noise becomes, particularly in low-luminance areas.

### SUMMARY OF THE INVENTION

The present invention has been made in consideration of the above situation, and enables a AΣ AD converter to perform AD conversion while applying gain.

According to the present invention, provided is an analog-to-digital converter comprising one or more processors and/or circuitry which function as: an analog-to-digital conversion unit that performs analog-to-digital conversion using ΔΣ modulation on an image signal output from pixels; a judgement unit that judges a gain to be applied to the image signal; and a control unit that controls a feedback amount used in the analog-to-digital conversion of the image signal by the analog-to-digital conversion unit based on the gain, wherein the control unit controls the feedback amount smaller in a case where the gain is a first gain than in a case where the gain is a second gain smaller than the first gain.

Further, according to the present invention, provided is a signal processing apparatus comprising: a plurality of the analog-to-digital converters each comprising one or more processors and/or circuitry which function as: an analog-to-digital conversion unit that performs analog-to-digital conversion using AΣ modulation on an image signal output from pixels; a judgement unit that judges a gain to be applied to the image signal; and a control unit that controls a feedback amount used in the analog-to-digital conversion of the image signal by the analog-to-digital conversion unit based on the gain, wherein the control unit controls the feedback amount smaller in a case where the gain is a first gain than in a case where the gain is a second gain smaller than the first gain, and in a case where the image signal is equal to or less than a second threshold, the control unit controls the feedback amount smaller than in a case where the image signal is greater than the second threshold; and a signal processing unit that applies a gain to digital signals obtained through the analog-to-digital conversion by the plurality of analog-to-digital converters, wherein the signal processing unit applies a gain according to a gain determined by the judgement unit and the feedback amount in a case where the image signal is equal to or less than a predetermined second threshold.

Furthermore, according to the present invention, provided is an image sensor comprising: a plurality of the analog-to-digital converters each comprising one or more processors and/or circuitry which function as: an analog-to-digital conversion unit that performs analog-to-digital conversion using AΣ modulation on an image signal output from pixels; a judgement unit that judges a gain to be applied to the image signal; and a control unit that controls a feedback amount used in the analog-to-digital conversion of the image signal by the analog-to-digital conversion unit based on the gain, wherein the control unit controls the feedback amount smaller in a case where the gain is a first gain than in a case where the gain is a second gain smaller than the first gain, and a plurality of the pixels.

Further, according to the present invention, provided is an electronic apparatus comprising: the image sensor comprising: a plurality of the analog-to-digital converters each comprising one or more processors and/or circuitry which function as: an analog-to-digital conversion unit that performs analog-to-digital conversion using ΔΣ modulation on an image signal output from pixels; a judgement unit that judges a gain to be applied to the image signal; and a control unit that controls a feedback amount used in the analog-to-digital conversion of the image signal by the analog-to-digital conversion unit based on the gain, wherein the control unit controls the feedback amount smaller in a case where the gain is a first gain than in a case where the gain is a second gain smaller than the first gain; and a plurality of the pixel; and a processing unit that processes digital signals obtained through the analog-to-digital conversion by the analog-to-digital converters.

Further, according to the present invention, provided is a control method for controlling an analog-to-digital converter that performs analog-to-digital conversion using ΔΣ modulation on an image signal output from pixels, comprising: judging a gain to be applied to the image signal; and controlling a feedback amount, used in the analog-to-digital conversion of the image signal, smaller in a case where the gain is a first gain than in a case where the gain is a second gain smaller than the first gain.

Further, according to the present invention, provided is a non-transitory computer-readable storage medium, the storage medium storing a program that is executable by the computer, wherein the program includes program code for causing the computer to execute each step of the method for controlling an analog-to-digital converter that performs analog-to-digital conversion using ΔΣ modulation on an image signal output from pixels, comprising: judging a gain to be applied to the image signal; and controlling a feedback amount, used in the analog-to-digital conversion of the image signal, smaller in a case where the gain is a first gain than in a case where the gain is a second gain smaller than the first gain.

Further features of the present invention will become apparent from the following description of exemplary embodiments (with reference to the attached drawings).

### BRIEF DESCRIPTION OF THE DRAWINGS

The accompanying drawings, which are incorporated in and constitute a part of the specification, illustrate embodiments of the invention, and together with the description, serve to explain the principles of the invention.

FIG. 1 is a block diagram illustrating a schematic configuration of an image capturing apparatus according to an embodiment of the present invention.

FIG. 2 is a block diagram illustrating a schematic configuration of an image sensor according to the embodiment.

FIG. 3 is a block diagram illustrating a configuration of a readout circuit according to the embodiment.

FIG. 4 is a block diagram illustrating a configuration of a ΔΣ ADC according to an embodiment.

FIG. 5A is a diagram illustrating examples of an input voltage and an output voltage of a comparator according to a first embodiment.

FIG. 5B is a diagram illustrating another examples of an input voltage and an output voltage of the comparator according to the first embodiment.

FIG. 6 is a flowchart illustrating an AD conversion operation in a case where a digital gain is replaced by a feedback amount according to the first embodiment.

FIG. 7 is a timing chart illustrating timings of luminance determination, switching of the feedback amount, and AD conversion according to the first embodiment.

FIG. 8 is an input/output characteristic diagram for non-Log and Log videos according to a second embodiment.

FIG. 9 is a diagram illustrating output with respect to each ISO input signal according to the second embodiment.

FIG. 10 is a flowchart illustrating the AD conversion operation according to the luminance of the input signal according to the second embodiment.

FIG. 11 is a diagram illustrating an example of a gamma curve in SDR mode and gamma curves in the PQ and HLG methods in HDR mode according to the second embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

### First Embodiment

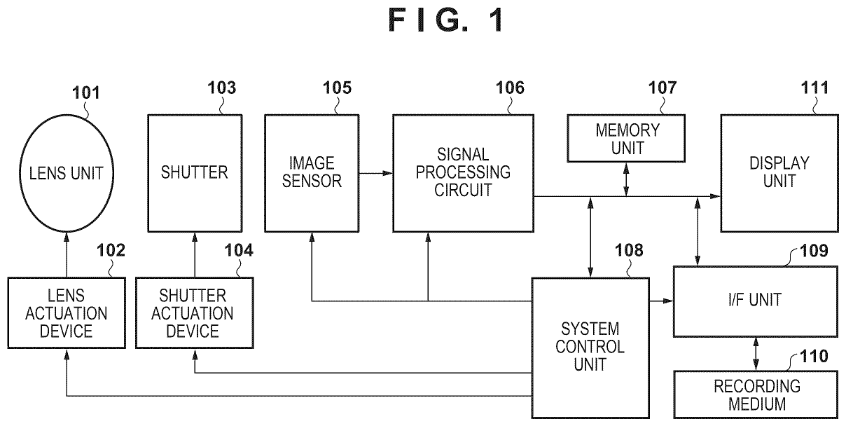

FIG. 1 is a block diagram illustrating a configuration of an image capturing apparatus using an image sensor according to a first embodiment of the present invention. Note that image capturing apparatus to which the present invention can be applied may be an electronic apparatus equipped with a camera function. Examples of electronic apparatuses include video cameras, computer devices (personal computers, tablet computers, media players, PDAs, etc.), mobile phones, smartphones, game machines, robots, drones, dashboard cameras, and so forth. These are merely examples, and the present invention can also be applied to other electronic apparatuses.

In FIG. 1, a lens unit 101 is comprised of a plurality of lenses including a zoom lens and a focus lens, and an aperture, and zoom control, focus control, aperture control, etc. are performed by a lens actuation device 102. An optical image of a subject incident through the lens unit 101 is formed on an image sensor 105. The lens unit 101 may be configured integrally with an image capturing apparatus, or may be configured to be detachable from an image capturing apparatus.

A mechanical shutter 103 is controlled by a shutter actuation device 104. The image sensor 105 photoelectrically converts the optical image of the subject formed by the lens unit 101 and outputs an image signal.

A signal processing circuit 106 performs digital gain processing for applying digital gain to the image signal output from the image sensor 105, various corrections, data compression, etc., and outputs image data. A memory unit 107 is used to temporarily store image data. A system control unit 108 performs various calculations and controls the entire image capturing apparatus. An I/F unit 109 is an interface for recording and/or reading data to/from a recording medium 110, which is a semiconductor memory such as a flash memory for holding image data, etc., and is configured to be removable. A display unit 111 displays various information and captured images.

Next, a brief description will be given of the operation of the image capturing apparatus having the above configuration during shooting.

When a main power switch (not shown) is turned on, the system control unit 108 is turned on, and then the imaging system circuits such as the signal processing circuit 106 are also turned on. Then, when shooting is instructed by pressing a release button (not shown), the shooting operation begins. When the shooting operation is completed, the image signal output from the image sensor 105 is subjected to image processing including various corrections and digital gain processing in the signal processing circuit 106, and the obtained image data is written to the memory unit 107 in response to the instruction from the system control unit 108. The image data held in the memory unit 107 is recorded in the removable recording medium 110 such as a semiconductor memory via the I/F unit 109 under the control of the system control unit 108.

Furthermore, RAW image data may be sent to a computer or the like via an external I/F unit (not shown), and image processing may be performed in the computer or the like.

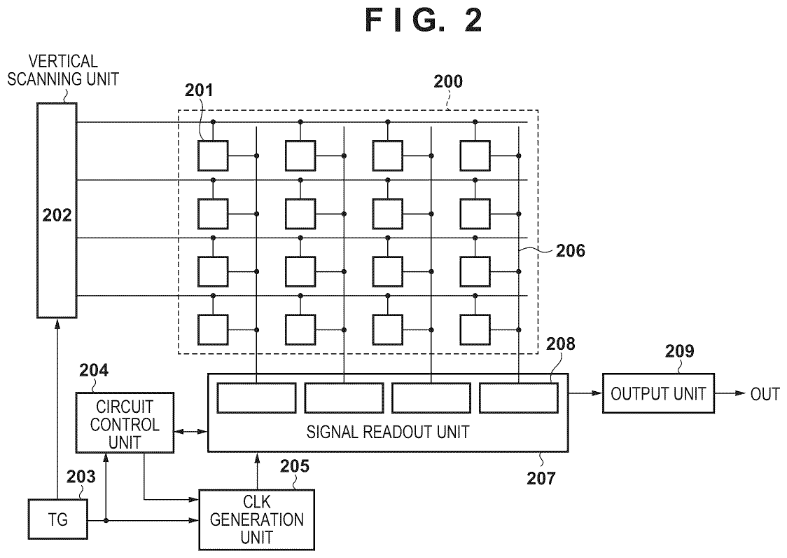

FIG. 2 is a block diagram illustrating a schematic configuration of the image sensor 105 in this embodiment.

The image sensor 105 includes a pixel section 200, a vertical scanning unit 202, a timing generator (TG) 203, a circuit control unit 204, a CLK generation unit 205, vertical transfer lines 206, a signal readout unit 207, and an output unit 209.

In the pixel section 200, a plurality of pixels 201 are arranged in a matrix. For ease of explanation, the pixels 201 are shown as forming a 4×4 pixel array in the pixel section 200, but in practice, a large number of pixels, for example, several millions or more of pixels, are arranged. The signal readout unit 207 includes a plurality of readout circuits 208.

The vertical scanning unit 202 selects the pixels 201 in the pixel section 200 in units of rows and supplies a plurality of actuation signals to each pixel 201 in the selected row. As a result, the pixel signals of the pixels 201 in the selected row are transferred to the signal readout unit 207 via the vertical transfer lines 206. The transferred pixel signals are converted into digital signals in the respective readout circuit 208 and output via the output unit 209.

The readout circuits 208 convert the input pixel signals into digital signal values of a predetermined number of bits by performing AD conversion. The AD conversion performed here uses the so-called AΣ AD conversion method.

The output unit 209 converts the digital signal value of each pixel into a predetermined signal format and outputs it from the image sensor 105 via a transmission path.

The TG 203 sends a timing signal to the vertical scanning unit 202, and the vertical scanning unit 202 generates an actuation signal for actuating the pixels 201 based on the timing signal to actuate the pixels 201. The circuit control unit 204 controls the CLK generation unit 205 and the signal readout unit 207 based on the timing signal from the TG 203. The CLK generation unit 205 generates a clock signal to be supplied to the signal readout unit 207 based on the timing signal supplied from the TG 203 and the control by the circuit control unit 204.

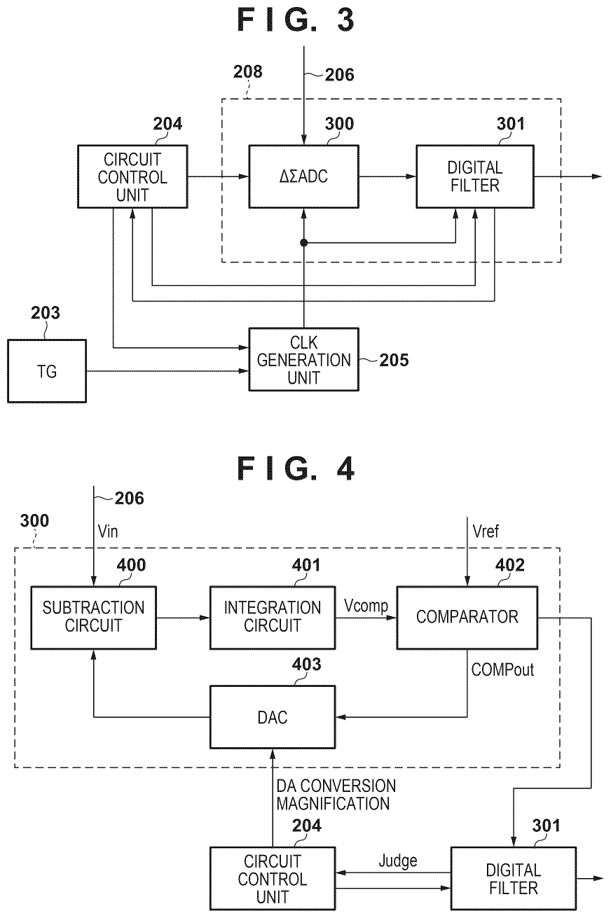

FIG. 3 is a block diagram illustrating the configuration of each readout circuit 208 shown in FIG. 2.

The readout circuits 208 include an analog-to-digital converter (ΔΣ ADC) 300 that uses ΔΣ modulation and a digital filter 301. The ΔΣ ADC 300 converts the pixel signals input via the vertical transfer lines 206 into digital signals using ΔΣ modulation. The digital filter 301 removes out-of-band quantization noise shifted to higher frequencies due to the ΔΣ modulation. It also performs thinning and taking a moving average of the high-rate output of the ΔΣ ADC 300 to reduce the output rate and convert it into a multi-bit signal value. The digital signal processed by the digital filter 301 is output to the output unit 209.

Furthermore, in a luminance detection process described below, the digital signal processed by the digital filter 301 is fed back to the circuit control unit 204. Based on this digital signal, the circuit control unit 204 controls the DA conversion magnification for controlling the amount of feedback in the AΣ ADC 300, or controls the digital filter 301 so as not to perform AD conversion. This control by the circuit control unit 204 will be described in detail later.

FIG. 4 is a block diagram illustrating the configuration of the AΣ ADC 300 shown in FIG. 3.

As shown in FIG. 4, the AΣ ADC 300 consists of a subtraction circuit 400, an integration circuit 401, a comparator 402, and a digital-to-analog converter (DAC) 403.

The subtraction circuit 400 outputs the difference between the pixel signal input via the vertical transfer line 206 and the output signal of the DAC 403 to the integration circuit 401. Note that a sample-and-hold circuit may be provided between the vertical transfer line 206 and the subtraction circuit 400, and in that case, the pixel signal output from the sample-and-hold circuit is input to the subtraction circuit 400.

The integration circuit 401 includes an integrator that integrates an input signal from the subtraction circuit 400. As the integration circuit 401, for example, a gm-C integration circuit using a transconductor, an RC integration circuit using an operational amplifier, or the like, which is a general integration circuit, may be used.

The comparator 402 compares the reference voltage Vref with the voltage signal output from the integration circuit 401 in synchronization with the clock signal, and outputs the comparison result as a 1-bit digital signal. For example, if the voltage signal output from the integration circuit 401 is lower than the reference voltage Vref, the comparator 402 outputs 0, and if the voltage signal is equal to or higher than the reference voltage Vref, the comparator 402 outputs 1. The digital signal is supplied to the digital filter 301 and the DAC 403.

The DAC 403 converts the digital signal output from the comparator 402 into a predetermined amount of analog signal and outputs it to the subtraction circuit 400. For example, when the digital signal output is 1, the DAC 403 outputs an analog signal (feedback amount) at a level according to a DA conversion magnification determined by the circuit control unit 204 as described later. Note that as the configuration of the DAC 403, various known circuitry may be used.

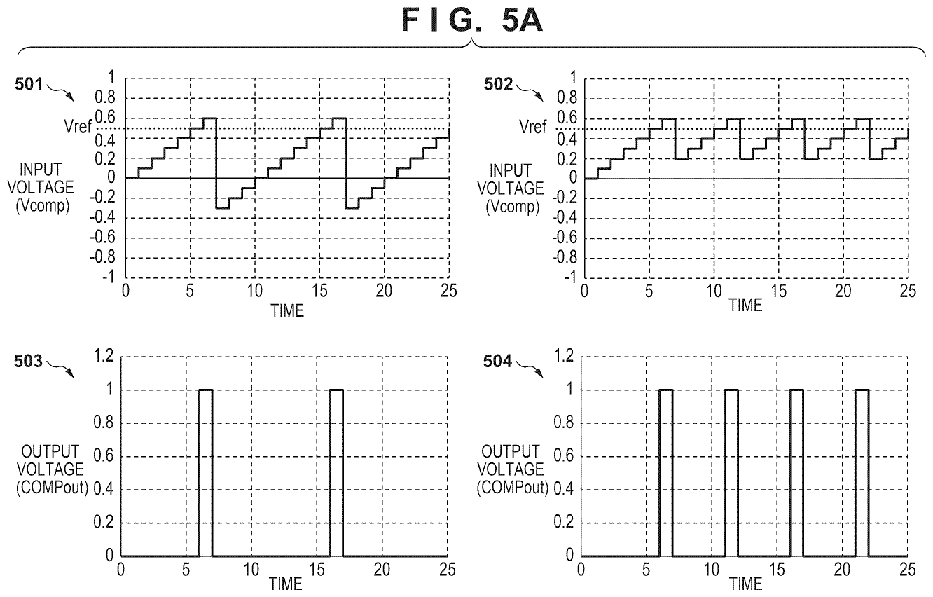

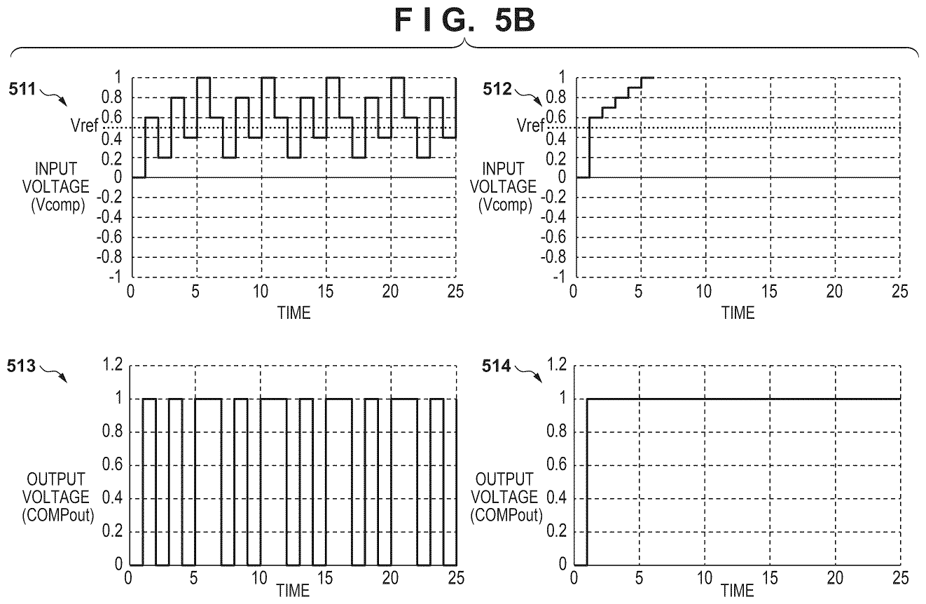

Next, the DA conversion magnification and the feedback amount in this embodiment will be described with reference to FIGS. 5A and 5B.

FIGS. 5A and 5B illustrate examples of an input voltage Vcomp to the comparator 402 and an output voltage COMPout from the comparator 402. Note that, in FIGS. 5A and 5B, the input/output voltage range is 1 V as an example.

The voltage waveform shown in FIG. 5A shows examples when the DAC 403 converts the digital signal output from the comparator 402 into an analog signal (feedback amount) using the different DA conversion magnifications with respect to the pixel signal of the same level Vin input to the AΣ ADC 300 via the vertical transfer lines 206. Such waveform patterns are repeated for a predetermined period.

A graph 501 shows the input voltage Vcomp to the comparator 402 and the reference voltage Vref, and a graph 503 shows the output voltage COMPout, which is a digital signal obtained by ΔΣ modulating the input voltage Vcomp shown in the graph 501 by the comparator 402. In contrast, a graph 502 shows the input voltage Vcomp to the comparator 402 and the reference voltage Vref in a case where a pixel signal Vin of the same level as that of the graph 501 is input and the amount of feedback input to the subtraction circuit 400 is halved by setting the DA conversion magnification to ½ that of the graph 501. A graph 504 shows the output voltage COMPout of the comparator 402 with respect to the input voltage Vcomp shown in the graph 502.

As will be understood from FIG. 5A, by setting the DA conversion magnification to ½ to halve the feedback amount, the number of times that the output signal COMPout from the comparator 402 becomes Hi doubles. In this way, by setting the DA conversion magnification of the DAC 403 to 1/N to reduce the feedback amount to 1/N, the number of times that the output signal COMPout from the comparator 402 becomes Hi, i.e., the number of times that Hi is output by AD conversion of the ΔΣ ADC 300, is increased by N times.

The voltage waveforms shown in FIG. 5B illustrate examples in which different DA conversion magnifications are used in a case where the level of the input pixel signal Vin is higher than the level of the pixel signal Vin shown in FIG. 5A.

A graph 511 shows an input voltage Vcomp to the comparator 402 and a reference voltage Vref in a case where the DA conversion magnification is the same as that of the graph 501. Further, a graph 512 shows an output signal COMPout of the comparator 402 with respect to the input voltage Vcomp shown in the graph 511. Compared to the graphs 501 and 503, in the graphs 511 and 513, the number of times that the output voltage COMPout becomes Hi as a result of AD conversion by the AΣ ADC 300 increases according to the level of the pixel signal Vin.

Moreover, a graph 512 shows an input voltage Vcomp to the comparator 402 and the reference voltage Vref in a case where the DA conversion magnification is set to ½ that of the graph 511 to halve the feedback amount input to the subtraction circuit 400 in a case where a pixel signal Vin of the same level as that of graph 511 is input. A graph 514 shows an output voltage COMPout of the comparator 402 with respect to the input voltage Vcomp shown in the graph 512. In this case, by setting the DA conversion magnification to ½ that of the graph 511, after a certain time, the output of the integration circuit 401 always becomes larger than 0, the input voltage Vcomp to the comparator 402 daiverges, and the operation of the AΣ ADC 300 becomes unstable.

In consideration of the above phenomenon, in this embodiment, the magnitude of the pixel signal is judged, and the DA conversion magnification to be used in the DAC 403 is determined depending on the judgement result.

Note that this judgement of the magnitude of the pixel signal may be made by performing AD conversion in advance at the resolution required for the judgement using the AΣ ADC 300, or may be made by providing a separate judgement circuit. As an example of a case where a separate judgement circuit is provided, for example, it may be configured to compare the voltage of the input pixel signal with a changeable comparison voltage, and output 0 or 1 depending on the comparison result. Note that the voltage indicating the comparison result is changed depending on the digital gain, as described below. An example of processing when using the AΣ ADC 300 will be described later.

Table 1 shows the relationship between ISO sensitivity, DA conversion magnification, digital gain, and bit precision.

TABLE 1

| | | | | | |
|---|---|---|---|---|---|
| | Bit | | Output | | Bit |
| | Precision | DA Conversion | Ratio | | Precision |
| ISO | of ADC | Magnification | of Comp | Dgain | of Output |

(a)

| | | | | | |
|---|---|---|---|---|---|
| 100 | 14 | 1 | 1 | 1 | 14 |
| 200 | 14 | 1 | 1 | 2 | 13 |
| 400 | 14 | 1 | 1 | 4 | 12 |
| 800 | 14 | 1 | 1 | 8 | 11 |
| 1600 | 14 | 1 | 1 | 16 | 10 |

(b)

| | | | | | |
|---|---|---|---|---|---|
| 100 | 14 | 1 | 1 | 1 | 14 |
| 200 | 14 | ½ | 2 | 1 | 14 |
| 400 | 14 | ¼ | 4 | 1 | 14 |
| 800 | 14 | ⅛ | 8 | 1 | 14 |
| 1600 | 14 | 1/16 | 16 | 1 | 14 |

Table 1(a) shows a case where the DA conversion magnification is set to 1 regardless of the ISO sensitivity, and the bit precision of the AD conversion including the processing by the digital filter is set to 14 bits at ISO 100. In this case, in order to increase the ISO sensitivity to ISO 200, ISO 400, etc., it is necessary to multiply the digital signal after AD conversion by a digital gain Dgain. Therefore, the bit precision of the final output becomes 1/Dgain, and in the case of ISO 1600, it becomes 10 bits. Furthermore, the image obtained by applying the digital gain Dgain is adversely affected by tone jumps and quantization noise being multiplied by the gain.

In order to eliminate these effects and to prevent the bit precision of the final output from decreasing regardless of the ISO sensitivity, in this embodiment, as shown in Table 1(b), the feedback amount is changed by changing the DA conversion magnification according to the ISO sensitivity. For example, by setting the DA conversion magnification to 1/16 at ISO 1600, the output ratio of comp indicating the output ratio of the comparator 402 is 16 times higher than that in a case where the feedback amount for ISO 100 (digital gain is 1×) is set as a result of AD conversion. In this way, it is possible to obtain an output equivalent to that when the digital gain Dgain is 16 without applying the digital gain Dgain. Furthermore, the bit precision of the final output becomes 14 bits, and the quantization noise is not amplified by the digital gain Dgain.

In the above example, the digital gain determined by the ISO sensitivity has been described, but the digital gain used for various corrections such as peripheral light falloff may be replaced with the feedback amount. That is, the DA conversion magnification is set to the reciprocal of the digital gain (1/Dgain) to make the feedback amount when the digital gain is 1 to the reciprocal of the digital gain. For example, in a situation in which a lens with a large peripheral light falloff is attached and digital gain needs to be applied at the peripheral part of the image according to the image height in peripheral illumination correction, by replacing the digital gain corresponding to the ISO sensitivity with the feedback amount as shown in Table 1(b) according to the image height, it is possible to reduce tone jumps and noise in the peripheral part of the image even after the correction.

Also, a part of the digital gain may be replaced by the feedback amount, and the AD conversion coefficient of the feedback amount and the digital gain may be used in combination. That is, the DA conversion magnification is set as the reciprocal of the digital gain divided by an integer, and is made smaller than the feedback amount when the digital gain is 1. Then, the digital gain is applied to compensate for the magnification that is not replaced by the feedback amount.

For high luminance input signals that become saturated when digital gain is applied, it is more efficient to control the digital filter 301 to output a signal indicating saturation without performing AD conversion. For example, when applying a digital gain of ×2 at ISO 200, signals that do not become saturated even when the gain is applied are signals that are equal to or less than ½ the input range of the AΣ ADC 300. In other words, if the input signal is larger than ½ the input range of the AΣ ADC 300, setting the DA conversion magnification to ½ and reducing the feedback amount to ½ will cause the operation of the AΣ ADC 300 to become unstable.

Therefore, when replacing a digital gain of ×2 with a DA conversion magnification of ½, the threshold is set to ½ of the input range to determine the luminance of the input signal, and if the input signal is equal to or less than the threshold, the digital gain is replaced with the DA conversion magnification of ½ and AD conversion is performed. On the other hand, if the input signal is greater than the threshold, performing AD conversion with the DA conversion magnification of ½ will not only result in saturation but will also cause the operation of the ΔΣ ADC 300 to become unstable, so the ΔΣ ADC 300 is controlled so as not to perform AD conversion itself.

As described above, the threshold for luminance determination for determining whether or not to perform AD conversion is determined according to the magnitude of the digital gain when the DA conversion magnification is 1, as shown in Table 1(a) according to ISO sensitivity and the contents of various corrections such as peripheral illumination correction. More specifically, 1/Dgain of the input range is determined as the threshold.

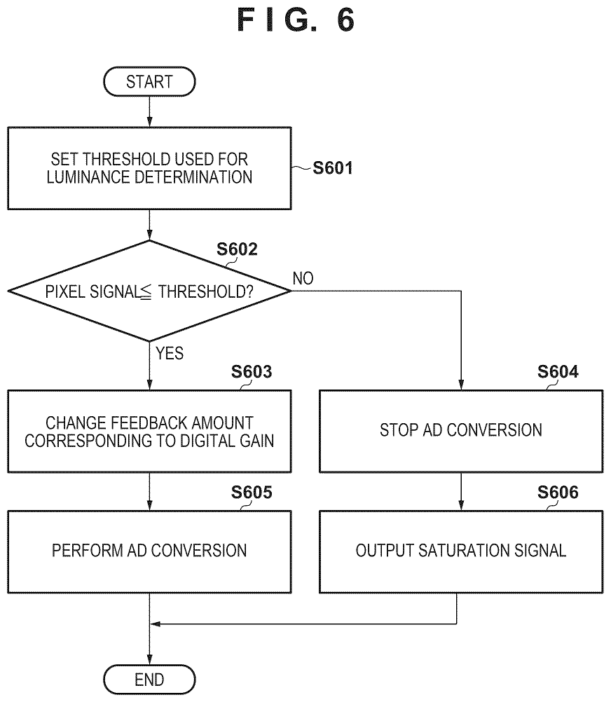

Next, the AD conversion operation in this embodiment in a case where the digital gain is replaced with the feedback amount (DA conversion magnification) will be described with reference to the flowchart in FIG. 6. This operation is repeated in each readout circuit 208 every time a new signal is input.

First, in step S601, the circuit control unit 204 sets a threshold used for the luminance determination according to the digital gain to be replaced with the feedback amount in the digital filter 301. For example, the threshold for the luminance determination is determined such that ½ of the input range of the AΣ ADC 300 is determined when the normal digital gain shown in Table 1(a) is ×2, and ¼ of the input range is determined when the digital gain is ×4.

In step S602, the digital filter 301 judges whether the input pixel signal is equal to or less than the threshold, and sends a Judge signal indicating the result of the judgement to the circuit control unit 204. If the Judge signal indicates that the pixel signal is equal to or less than the threshold, in step S603, the circuit control unit 204 transmits a DA conversion magnification according to the digital gain to be replaced to the DAC 403, and the DAC 403 changes the feedback amount according to the DA conversion magnification. Then, in step S605, the ΔΣ ADC 300 performs AD conversion.

On the other hand, if the input pixel signal is greater than the threshold, the operation of the ΔΣ ADC 300 becomes unstable if the digital gain is replaced with the feedback amount and AD conversion is performed, so the AD conversion is stopped in step S604. Then, in step S606, the circuit control unit 204 controls the digital filter 301 to output a saturation signal.

When the process of step S605 or S606 is completed, the process for one pixel signal is completed.

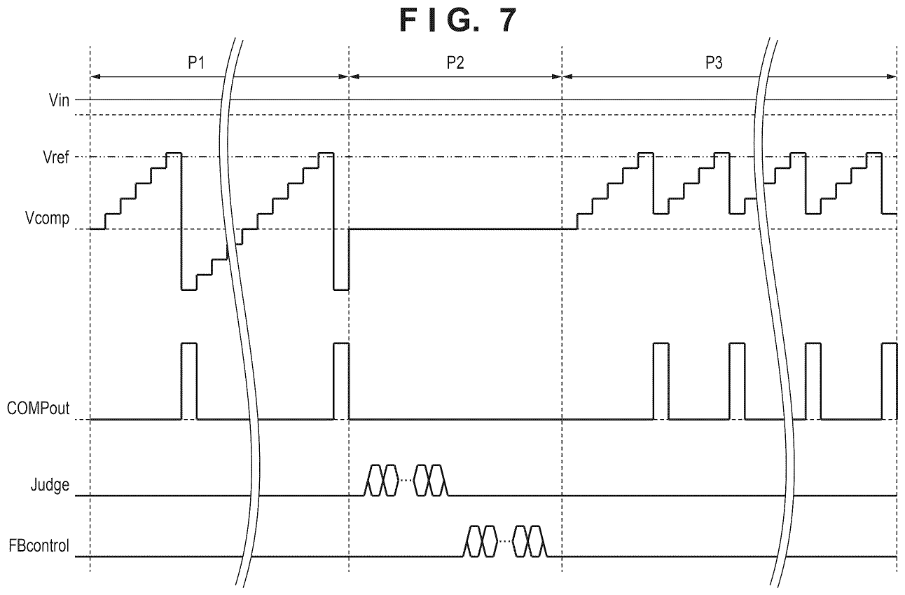

FIG. 7 is a timing chart showing the processes from steps S601 to S605 in a case where the input pixel signal is equal to or lower than the threshold. In FIG. 7, a period P1 corresponds to the processes in steps S601 and S602, a period P2 corresponds to the process in step S603, and a period P3 corresponds to the process in step S605.

In the period P1 in FIG. 7, the circuit control unit 204 sets a threshold in the digital filter 301 based on a digital gain to be replaced with the feedback amount. The digital filter 301 does not change the feedback amount by setting the DA conversion magnification of the DAC 403 to 1, compares the digital signal obtained by performing AD conversion on the input voltage Vcomp to the comparator 402 with low bit accuracy in a short period of time with the set threshold, and outputs a Judge signal indicating the comparison result.

Next, in the period P2, the circuit control unit 204 controls the DA conversion magnification of the DAC 403 based on the Judge signal input from the digital filter 301 in the period P1.

Here, since the digital signal of the input pixel signal is equal to or lower than the threshold, AD conversion is performed in a state in which the feedback amount of the DAC 403 is adjusted by the DA conversion magnification in the period P3. For example, if ISO200 is selected, the circuit control unit 204 controls the DAC 403 to have ½ the DA conversion magnification set therein, so that the feedback amount is halved. As a result, the feedback amount from the DAC 403 when the output voltage COMPout becomes Hi is reduced, so that the waveform of the input voltage Vcomp to the comparator 402 in the period P3 is different from that in the period P1, and the cycle in which the output voltage COMPout becomes Hi is ½ that in the period P1.

As described above, according to the first embodiment, by replacing the digital gain with the feedback amount, it is possible to obtain an output equivalent to that amplified by the digital gain while not reducing the bit precision of the final output, and to obtain a good image with suppressed tone jumps and quantization noise.

Furthermore, in a case where the input signal is greater than the threshold, by controlling a saturated signal to be output without performing AD conversion, it is possible to convert the input signal into a digital signal without impairing the stability of the ΔΣ ADC.

### Second Embodiment

Next, a second embodiment of the present invention will be described.

In the second embodiment, a method for reducing noise in an input signal with low luminance by changing the amount of feedback will be described. Note that the image capturing apparatus in the second embodiment can be the same as that described with reference to FIGS. 1 to 4 in the first embodiment, and therefore a description thereof will be omitted.

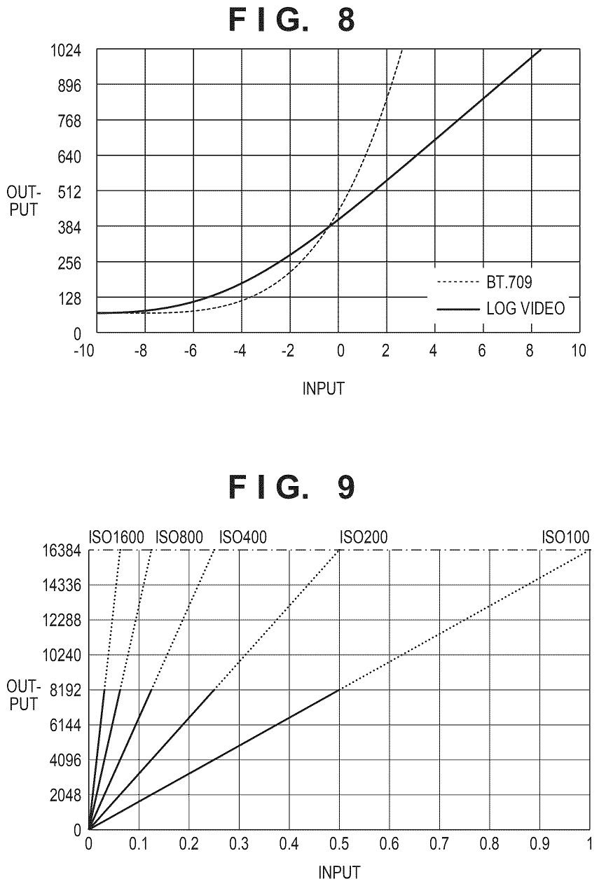

In order to obtain a wide dynamic range, a Log video having input/output characteristics different from normal characteristics is known as one of shooting modes. The Log video has input/output characteristics as shown in FIG. 8, for example. The horizontal axis of FIG. 8 indicates the number of stops when 18% gray is set to 0, and the vertical axis indicates the signal level in a 10-bit recording file. A dashed line indicates the characteristics of BT.709 in a non-Log format, and a solid line indicates the characteristics of the Log video. As shown in FIG. 8, the slope in the dark region is steeper in the Log video and more signal levels are allocated to the dark region than in BT.709, therefore, the dark gradation is enriched. On the other hand, the noise in the dark region is noticeable because it is in a state where a high gain is applied.

In contrast, in the second embodiment, for low luminance signals, the signals are amplified without amplifying the quantization noise by changing the feedback amount, and the amplified amount is divided by the gain to reduce the quantization noise.

Table 2 shows the relationship between ISO sensitivity, DA conversion magnification, dividing gain, digital gain, and bit precision in the second embodiment. Note that, in the second embodiment, the ISO sensitivity and the digital gain are assumed to correspond to each other.

TABLE 2

| | Threshold T1 | Threshold T2 | Dgain |
|---|---|---|---|
| ISO | (Magnification) | (Magnification) | (ISO) |
| 100 | ×1 | ×½ | 1 |
| 200 | ×½ | ×¼ | 2 |
| 400 | ×¼ | ×⅛ | 4 |
| 800 | ×⅛ | × 1/16 | 8 |
| 1600 | × 1/16 | × 1/32 | 16 |

(a)

(Vin ≤ Th2)

| | Bit | | Output | | | Bit |
|---|---|---|---|---|---|---|
| | Precision | DA Conversion | Ratio | Dividing | Dgain | Precision |
| ISO | of ADC | Magnification | of Comp | Gain | (ISO) | of Output |
| 100 | 14 | ½ | 2 | ½ | 1 | 14 |
| 200 | 14 | ¼ | 4 | ½ | 1 | 14 |
| 400 | 14 | ⅛ | 8 | ½ | 1 | 14 |
| 800 | 14 | 1/16 | 16 | ½ | 1 | 14 |
| 1600 | 14 | 1/32 | 32 | ½ | 1 | 14 |

(b)

(Th2 < Vin ≤ Th1)

| | Bit | | Output | | | Bit |
|---|---|---|---|---|---|---|
| | Precision | DA Conversion | Ratio | Dividing | | Precision |
| ISO | of ADC | Magnification | of Comp | Gain | Dgain | of Output |
| 100 | 14 | 1 | 1 | 1 | 1 | 14 |
| 200 | 14 | ½ | 2 | 1 | 1 | 14 |
| 400 | 14 | ¼ | 4 | 1 | 1 | 14 |
| 800 | 14 | ⅛ | 8 | 1 | 1 | 14 |
| 1600 | 14 | 1/16 | 16 | 1 | 1 | 14 |

(c)

Table 2(a) shows the relationship between ISO sensitivity, thresholds, and digital gain in the second embodiment. A threshold Th1 is a threshold for determining whether the operation of the AΣ ADC 300 becomes unstable, and a threshold Th2 is a threshold for determining whether a noise will be reduced by changing the feedback amount. As described in the first embodiment, the threshold is determined according to the input range of the AΣ ADC 300, so Table 2(a) shows a magnification with respect to the input range. Therefore, the threshold Th1 and the threshold Th2 are each a value obtained by multiplying the input range by the magnification shown in Table 2(a). The method of comparing the input signal with the threshold is the same as the method described in the first embodiment, so the description thereof will be omitted.

Table 2(b) shows a case where the pixel signal Vin is a low luminance signal equal to or lower than the threshold Th2. Here, by further dividing the DA conversion magnification by 2, the output on the low luminance side is amplified without amplifying the quantization noise compared to the first embodiment. Then, the amplification amount is divided by the digital gain to further compress the quantization noise. For example, in the case of ISO 100, the threshold Th2 is ½ the input range of the AΣ ADC 300, so by setting the DA conversion magnification to ½, the input of low luminance equal to or lower than the threshold Th2 is doubled while AD conversion without using digital gain, and by multiplying the AD conversion result by the dividing gain of ½, the quantization noise can be halved. The dividing gain is equal to the threshold Th2 divided by the threshold Th1. In this way, if the luminance is equal to or lower than the threshold Th2, the noise can be reduced as described above.

Table 2(c) shows a case where the pixel signal Vin indicates a medium luminance which is greater than the threshold Th2 and equal to or less than the threshold Th1, and the DA conversion magnification is changed according to the luminance to perform AD conversion and the dynamic range on the high luminance side is expanded. For example, at ISO 200, by setting the DA conversion magnification to ½, AD conversion that doubles the input signal is performed without using digital gain. In addition, no multiplication using the dividing gain is performed. This process is the same as the process in the first embodiment. As a result, by changing the feedback amount instead of the digital gain for pixel signals of medium luminance, it is possible to obtain a good image with suppressed tone jumps and quantization noise without reducing the bit precision of the final output.

When the input pixel signal Vin is a high luminance signal exceeding the threshold Th1, the AD conversion is stopped as in the first embodiment. Then, by controlling the digital filter 301 to output a saturation signal, the signal can be converted into a digital signal without impairing the stability of the operation of the ΔΣ ADC 300.

FIG. 9 shows the output for the input signal at each ISO. The solid line portions of each ISO shown in FIG. 9 correspond to low luminance below the threshold Th2, and show the outputs for the input signals after AD conversion using the DA conversion magnifications shown in Table 2(b) and multiplied by the dividing gain. The dashed line portions correspond to medium luminance above the threshold Th2 and below the threshold Th1, and show the outputs for the input signals after AD conversion using the DA conversion magnifications shown in Table 2(c) and multiplied by the dividing gain. Furthermore, the dot-dash line portion correspond to high luminance above the threshold Th1, and the outputs for the input signals are a saturated signal.

For example, in the example shown in FIG. 9, for ISO 200, the threshold Th1 at which a digital gain can be replaced with the feedback amount is 0.5, which is half the threshold Th1 of 1 for ISO 100. Also, the input range at which the output of the AD conversion at ISO 200 becomes saturated is half that of ISO 100, so if less than half the output range of the AD conversion is considered to be a dark portion, the threshold Th2 in order to reduce a noise is 0.25, which is half the threshold Th1 of 0.5 for ISO 100.

In addition, in FIG. 9, the input corresponding to 8192 LSB, which is the median value of the 14-bit output at each ISO sensitivity, is set as the threshold Th2.

In this way, a threshold is set to divide the input signal into low luminance, medium luminance, and high luminance, and AD conversion is performed by changing DA conversion magnification and dividing gain according to the luminance.

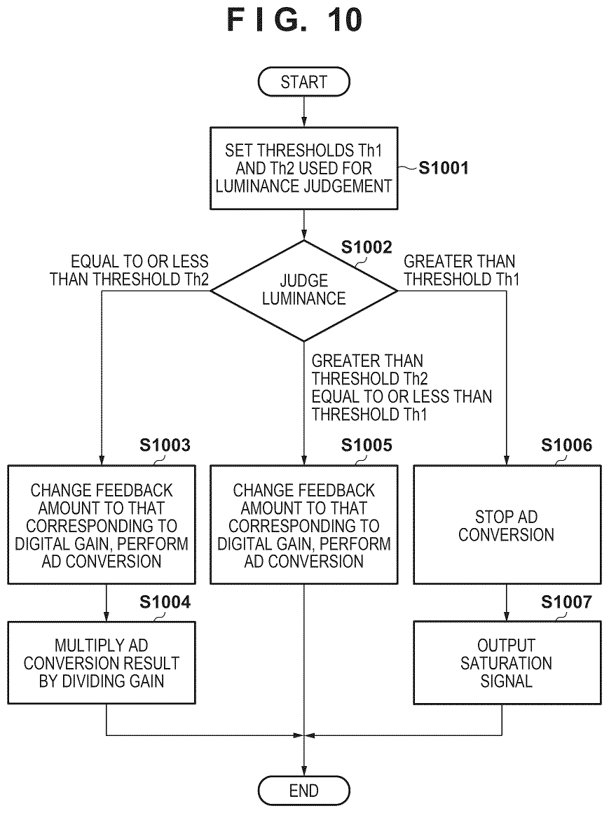

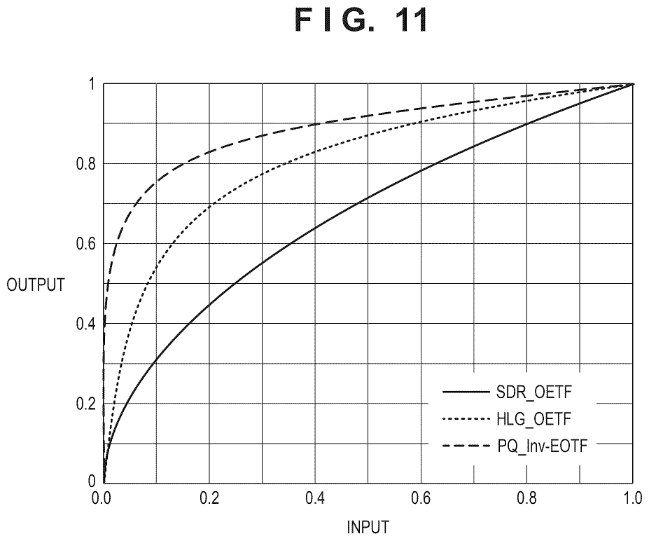

Next, the flow of the AD conversion operation according to the luminance of the input signal in the second embodiment will be described with reference to a flowchart in FIG. 10. Note that this operation is repeatedly performed in each readout circuit 208 every time a new signal is input.

First, in step S1001, the circuit control unit 204 sets the thresholds Th1 and Th2 used for luminance judgement in the digital filter 301 according to the digital gain. The thresholds Th1 and Th2 can be determined based on Table 2(a). Next, in step S1002, the digital filter 301 compares the input pixel signal with the thresholds Th1 and Th2, and sends a Judge signal indicating the comparison result to the circuit control unit 204. Note that in a case where this luminance judgement is performed using the AΣ ADC 300, if the settings are as shown in Table 2(b), it is necessary to judge the smallest threshold, 1/32, and therefore a resolution greater than or equal to this is required.

If the Judge signal indicates that the pixel signal is equal to or less than the threshold Th2, the circuit control unit 204 transmits the DA conversion magnification to the DAC 403 in step S1003, and the DAC 403 changes the feedback amount to that corresponding to the DA conversion magnification and performs AD conversion. Then, in step S1004, the digital signal obtained by the AD conversion is multiplied by the dividing gain. The DA conversion magnification and dividing gain at this time are determined according to the ISO, as shown in Table 2(b).

Also, in a case where the Judge signal indicates that the pixel signal exceeds the threshold Th2 and is equal to or less than the threshold Th1, the circuit control unit 204 transmits the DA conversion magnification to the DAC 403 in step S1005, and the DAC 403 changes the feedback amount to that corresponding to the DA conversion magnification and performs AD conversion. The DA conversion magnification at this time is determined according to the ISO as shown in Table 2(c). Also, magnification by dividing gain is not performed.

Furthermore, if the Judge signal indicates that the pixel signal exceeds the threshold Th1, the AD conversion by the AΣ ADC 300 becomes unstable. Therefore, the AD conversion is stopped in step S1006, and in step S1007 the circuit control unit 204 controls the digital filter 301 to output a saturation signal.

When the processing of step S1004, S1005, or S1006 is completed, the processing for one pixel signal is completed.

In the above example, the DA conversion magnification and the dividing gain are determined according to the ISO sensitivity. However, as in the first embodiment, the DA conversion magnification and the dividing gain may be determined according to the digital gain used for various corrections such as peripheral illumination correction.

FIG. 11 shows gamma curves of the Standard Dynamic Range (SDR) mode and the Perceptual Quantization (PQ) method and the Hybrid Log Gamma (HLG) method in the High Dynamic Range (HDR) mode as another example of a shooting mode other than the Log video mode. The solid line shows an example of the gamma curve of the SDR, the dotted line shows an example of the HLG, and the dashed line shows an example of the PQ. Also, unlike FIG. 8, the horizontal axis shows the luminance. As with the Log video, by assigning more signal level to the dark portion in the HLG than in the SDR, the dark gradation becomes richer, while the noise in the dark portion becomes more noticeable. This tendency is even more pronounced in the PQ method. Therefore, in the case of low luminance, the feedback amount is changed and the multiplied output is divided back by the digital gain to compress the quantization noise, and in the case of high luminance, AD conversion is performed without changing the feedback amount, thereby the noise in the dark portion can be reduced. Therefore, even in the SDR still image, the second embodiment can be applied as a high-quality still image mode. In addition to the above, the control in this embodiment may be applied in the live view mode.

As described above, according to the second embodiment, the feedback amount and the dividing gain are controlled in accordance with the luminance of the input signal, thereby making it possible to further reduce dark noise.

In the above embodiment, a first-order AΣ modulator constituting a first-order loop filter is described, but the present invention can also be applied to a circuit configuration using a second-order or higher-order ΔΣ modulator to stabilize the feedback loop. In the case of using a second-order or higher-order ΔΣ modulator, the feedback amount may be changed for each feedback loop. Furthermore, the subtraction circuit 400 may be an addition circuit.

Also, in an incremental type ΔΣ ADC, although the digital signal waveform differs from those shown in FIGS. 5A and 5B, the effect of changing the feedback amount can be obtained in the same way.

### OTHER EMBODIMENTS

The present invention may be applied to a system consisting of multiple devices, or to an apparatus consisting of a single device.

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-074921, filed May 2, 2024 which is hereby incorporated by reference herein in its entirety.

What is claimed is:

1. An analog-to-digital converter comprising one or more processors and/or circuitry which function as:
an analog-to-digital conversion unit that performs analog-to-digital conversion using ΔΣ modulation on an image signal output from pixels;
a judgement unit that judges a gain to be applied to the image signal; and
a control unit that controls a feedback amount used in the analog-to-digital conversion of the image signal by the analog-to-digital conversion unit based on the gain,
wherein the control unit controls the feedback amount smaller in a case where the gain is a first gain than in a case where the gain is a second gain smaller than the first gain.

2. The analog-to-digital converter according to claim 1, wherein the control unit multiplies the feedback amount used in a case where the gain applied to the image signal is 1 by a reciprocal of the gain judged by the judgement unit.

3. The analog-to-digital converter according to claim 1, wherein the control unit controls the feedback amount between a first feedback amount used in a case where the gain to be applied to the image signal is 1 and a second feedback amount obtained by multiplying the first feedback amount by a reciprocal of the gain judged by the judgement unit.

4. The analog-to-digital converter according to claim 1, wherein the judgement unit judges the gain based on at least one of ISO sensitivity and a correction method including correction of peripheral light falloff.

5. The analog-to-digital converter according to claim 1, wherein
the control unit further controls an output of the analog-to-digital conversion unit, and
in a case where the image signal is greater than a predetermined first threshold, the control unit controls the analog-to-digital conversion unit to output a predetermined value without performing the analog-to-digital conversion.

6. The analog-to-digital converter according to claim 5, wherein the first threshold is a value obtained by dividing an input range in which the analog-to-digital conversion unit can perform the analog-to-digital conversion by the gain.

7. The analog-to-digital converter according to claim 1, wherein in a case where the image signal is equal to or less than a second threshold, the control unit controls the feedback amount smaller than in a case where the image signal is greater than the second threshold.

8. The analog-to-digital converter according to claim 7, wherein the second threshold is obtained by dividing a value, obtained by dividing an input range in which the analog-to-digital conversion unit can perform the analog-to-digital conversion by the gain, by an integer.

9. The analog-to-digital converter according to claim 7, wherein in a case where a predetermined shooting mode is set, the control unit controls the feedback amount based on a comparison result between the image signal and the second threshold.

10. The analog-to-digital converter according to claim 9, wherein the predetermined shooting mode includes at least one of a high-quality still image mode, a still image mode, a Log video mode, a video mode, a live view mode, and a Hybrid Log Gamma (HLG) method and a Perceptual Quantization (PQ) method in a High Dynamic Range (HDR) mode.

11. The analog-to-digital converter according to claim 1, wherein the analog-to-digital conversion unit includes:
a digital-to-analog conversion unit;
a subtraction unit that subtracts a signal output from the digital-to-analog conversion unit from the image signal;
an integration unit that integrates a signal output from the subtraction unit; and
a comparison unit that compares a signal output from the integration unit with a predetermined threshold and outputs a comparison result,
wherein the digital-to-analog conversion unit outputs a signal indicating a feedback amount to the subtraction unit according to the comparison result, and
wherein the control unit controls the feedback amount in the digital-to-analog conversion unit.

12. A signal processing apparatus comprising:
a plurality of the analog-to-digital converters each comprising one or more processors and/or circuitry which function as:
an analog-to-digital conversion unit that performs analog-to-digital conversion using ΔΣ modulation on an image signal output from pixels;
a judgement unit that judges a gain to be applied to the image signal; and
a control unit that controls a feedback amount used in the analog-to-digital conversion of the image signal by the analog-to-digital conversion unit based on the gain,
wherein the control unit controls the feedback amount smaller in a case where the gain is a first gain than in a case where the gain is a second gain smaller than the first gain, and
in a case where the image signal is equal to or less than a second threshold, the control unit controls the feedback amount smaller than in a case where the image signal is greater than the second threshold; and
a signal processing unit that applies a gain to digital signals obtained through the analog-to-digital conversion by the plurality of analog-to-digital converters,
wherein the signal processing unit applies a gain according to a gain determined by the judgement unit and the feedback amount in a case where the image signal is equal to or less than a predetermined second threshold.

13. An image sensor comprising:
a plurality of the analog-to-digital converters each comprising one or more processors and/or circuitry which function as:
an analog-to-digital conversion unit that performs analog-to-digital conversion using ΔΣ modulation on an image signal output from pixels;
a judgement unit that judges a gain to be applied to the image signal; and
a control unit that controls a feedback amount used in the analog-to-digital conversion of the image signal by the analog-to-digital conversion unit based on the gain,
wherein the control unit controls the feedback amount smaller in a case where the gain is a first gain than in a case where the gain is a second gain smaller than the first gain, and
a plurality of the pixels.

14. An electronic apparatus comprising:
the image sensor comprising:
a plurality of the analog-to-digital converters each comprising one or more processors and/or circuitry which function as:
an analog-to-digital conversion unit that performs analog-to-digital conversion using ΔΣ modulation on an image signal output from pixels;
a judgement unit that judges a gain to be applied to the image signal; and
a control unit that controls a feedback amount used in the analog-to-digital conversion of the image signal by the analog-to-digital conversion unit based on the gain,
wherein the control unit controls the feedback amount smaller in a case where the gain is a first gain than in a case where the gain is a second gain smaller than the first gain; and
a plurality of the pixel; and
a processing unit that processes digital signals obtained through the analog-to-digital conversion by the analog-to-digital converters.

15. A control method for controlling an analog-to-digital converter that performs analog-to-digital conversion using ΔΣ modulation on an image signal output from pixels, comprising:
judging a gain to be applied to the image signal; and
controlling a feedback amount, used in the analog-to-digital conversion of the image signal, smaller in a case where the gain is a first gain than in a case where the gain is a second gain smaller than the first gain.

16. A non-transitory computer-readable storage medium, the storage medium storing a program that is executable by the computer, wherein the program includes program code for causing the computer to execute each step of the method for controlling an analog-to-digital converter that performs analog-to-digital conversion using ΔΣ modulation on an image signal output from pixels, comprising:
judging a gain to be applied to the image signal; and
controlling a feedback amount, used in the analog-to-digital conversion of the image signal, smaller in a case where the gain is a first gain than in a case where the gain is a second gain smaller than the first gain.
